(19) United States
(12) Patent Application Publication
(10) Pub. No.: US 2019/0296044 A1
(43) Pub. Date: Sep. 26, 2019

(54) SEMICONDUCTOR MEMORY DEVICE AND METHOD FOR MANUFACTURING SAME

(71) Applicant: TOSHIBA MEMORY CORPORATION, Minato-ku (JP)

(72) Inventors: Kazunori HARADA, Kawasaki (JP); Takuya KONNO, Yokkaichi (JP); Daisuke HAGISHIMA, Meguro (JP)

(73) Assignee: TOSHIBA MEMORY CORPORATION, Minato-ku (JP)

(21) Appl. No.: 16/128,666

(22) Filed: Sep. 12, 2018

(30) Foreign Application Priority Data
Mar. 22, 2018 (JP) 2018-054600

(51) Int. Cl. H01L 27/11582; H01L 27/1157

(52) U.S. Cl. CPC H01L 27/11582; H01L 21/31116; H01L 27/1157

(57) ABSTRACT

According to an embodiment, a semiconductor memory device includes a substrate, a stacked body and a columnar portion. The columnar portion is provided inside the stacked body and includes a semiconductor portion extending in a first direction. The columnar portion has widths having mutually-different sizes in a second direction perpendicular to the first direction. The widths include first and second widths. The first width is a width of the columnar portion positioned inside a first electrode film of lowermost layer of the electrode films. The first width is substantially the same width at positions in the first direction of the columnar portion. The second width is a width of the columnar portion positioned inside a second electrode film of the electrode films. The second width is substantially the same width at positions in the first direction of the columnar portion. The first width is smaller than the second width.

### CROSS-REFERENCE TO RELATED APPLICATIONS

This application is based upon and claims the benefit of priority from Japanese Patent Application No. 2018-054600, filed on Mar. 22, 2018; the entire contents of which are incorporated herein by reference.

### FIELD

Embodiments relate generally to a semiconductor memory device and a method for manufacturing the same.

### BACKGROUND

A semiconductor memory device that has a three-dimensional structure has been proposed in which a memory hole is formed in a stacked body in which multiple electrode films are stacked, and a channel is provided inside the memory hole. Among the multiple electrode films, electrode films that are provided at the upper layer and the lower layer of the stacked body function as gate electrodes of select transistors; and a memory string is configured by connecting, via the channel, the select transistors and the memory cells positioned between the select transistors. In such a semiconductor memory device, it is desirable to improve the electrical characteristics of the electrode films functioning as the gate electrodes of the select transistors.

### BRIEF DESCRIPTION OF THE DRAWINGS

FIG. 1 is a perspective view showing a semiconductor memory device according to a first embodiment;

FIG. 2 is a cross-sectional view showing a portion of the semiconductor memory device according to the first embodiment;

FIG. 3 is a top view showing a portion of the semiconductor memory device according to the first embodiment;

FIG. 4A and FIG. 4B are drawings showing electrical characteristics of the semiconductor memory device according to the first embodiment;

FIG. 5A and FIG. 5B are cross-sectional views showing a method for manufacturing the semiconductor memory device according to the first embodiment;

FIG. 6A and FIG. 6B are cross-sectional views showing a method for manufacturing the semiconductor memory device according to the first embodiment;

FIG. 7A and FIG. 7B are cross-sectional views showing a method for manufacturing the semiconductor memory device according to the first embodiment;

FIG. 8 is a cross-sectional view showing a portion of a semiconductor memory device according to a second embodiment;

FIG. 9 is a top view showing a portion of the semiconductor memory device according to the second embodiment;

FIG. 10A and FIG. 1013 are cross-sectional views showing a method for manufacturing the semiconductor memory device according to the second embodiment;

FIG. 11A and FIG. 11B are cross-sectional views showing a method for manufacturing the semiconductor memory device according to the second embodiment;

FIG. 12 is a cross-sectional view showing a portion of a semiconductor memory device according to a third embodiment;

FIG. 13 is a top view showing a portion of the semiconductor memory device according to the third embodiment;

FIG. 14A and FIG. 14B are cross-sectional views showing a method for manufacturing the semiconductor memory device according to the third embodiment; and

FIG. 15A and FIG. 15B are cross-sectional views showing a method for manufacturing the semiconductor memory device according to the third embodiment.

### DETAILED DESCRIPTION

According to an embodiment, a semiconductor memory device includes a substrate, a stacked body, and a columnar portion. The stacked body is provided on the substrate and includes a plurality of electrode films stacked in a first direction to be separated from each other. The columnar portion is provided inside the stacked body and includes a semiconductor portion extending in the first direction. The columnar portion has a plurality of widths having mutually-different sizes in a second direction perpendicular to the first direction. The plurality of widths includes a first width and a second width. The first width is a width of the columnar portion positioned inside a first electrode film of a lowermost layer of the plurality of electrode films. The first width is substantially the same width at positions in the first direction of the columnar portion. The second width is a width of the columnar portion positioned inside a second electrode film of the plurality of electrode films. The second width is substantially the same width at positions in the first direction of the columnar portion. The first width is smaller than the second width.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

### First Embodiment

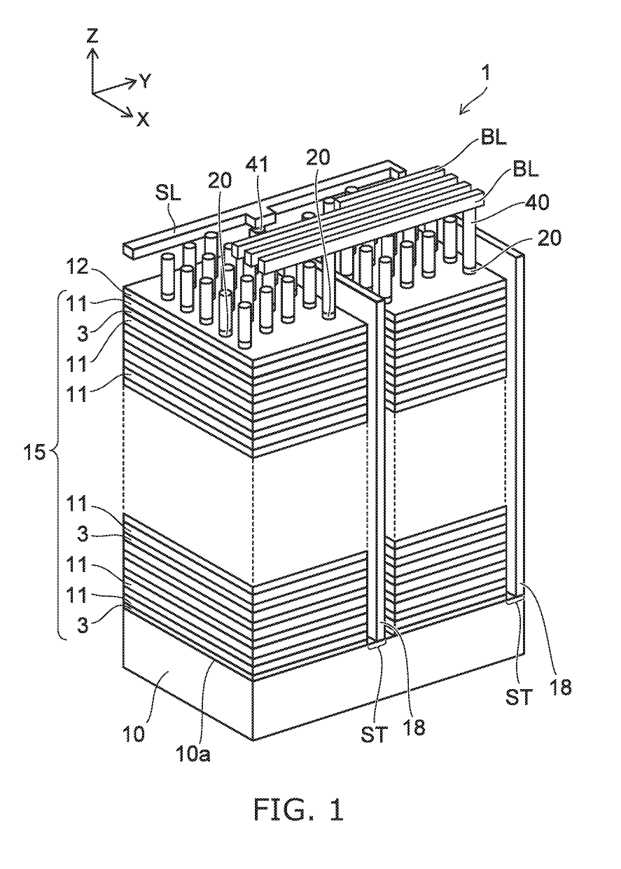

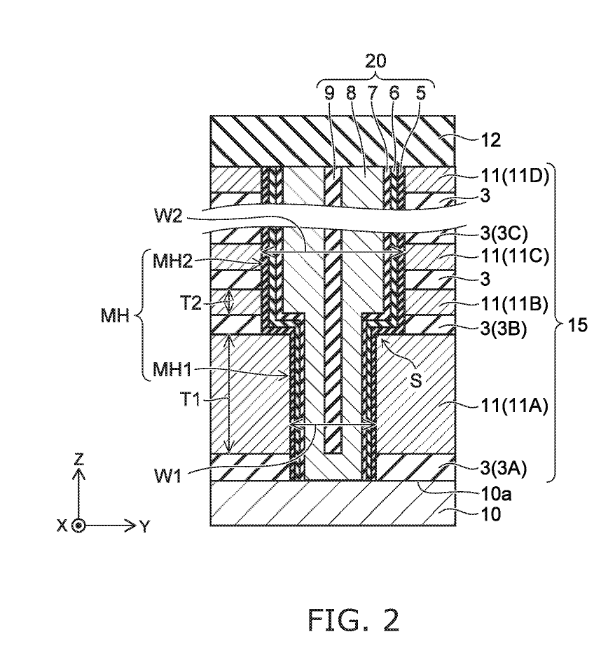

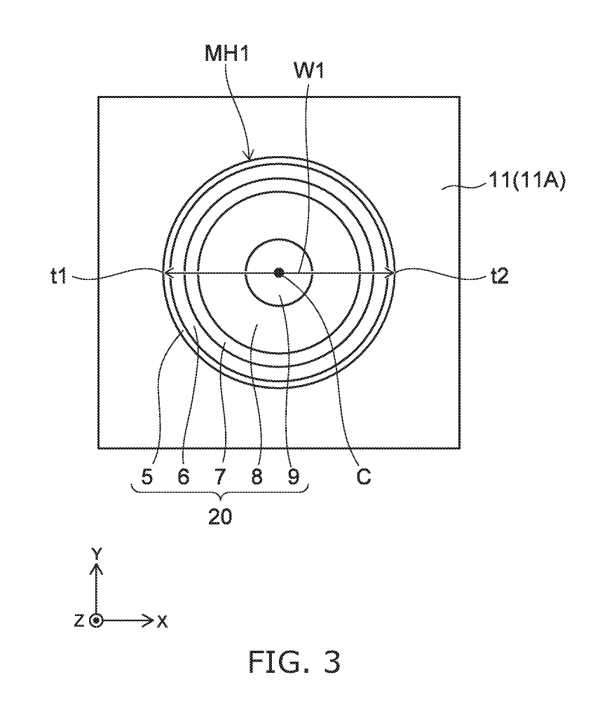

FIG. 1 is a perspective view of a semiconductor memory device 1. FIG. 2 is a cross-sectional view of a portion of the semiconductor memory device 1. FIG. 3 is a top view of a portion of the semiconductor memory device 1.

As shown in FIG. 1, a substrate 10 is provided in the semiconductor memory device 1. The substrate 10 includes, for example, silicon (Si). Here, in the specification, two mutually-orthogonal directions parallel to an upper surface 10a of the substrate 10 are taken as an X-direction (a second direction) and a Y-direction (a second direction). A direction orthogonal to both the X-direction and the Y-direction is taken as a Z-direction (a first direction). FIG. 2 shows a Y-Z cross section of the semiconductor memory device 1; and FIG. 3 shows the X-Y plane of the semiconductor memory device 1.

A stacked body 15, columnar portions 20, and interconnect portions 18 are provided in the semiconductor memory device 1.

The stacked body 15 is provided on the substrate 10. The stacked body 15 includes multiple electrode films 11 and multiple insulating films 3. For example, the electrode films 11 include a metal such as tungsten (W), etc. The electrode films 11 may include polysilicon made of amorphous silicon that is crystallized. The insulating films 3 include silicon oxide (SiO), etc. The insulating films 3 are inter-layer insulating films provided between the electrode films 11. The number of stacks of the electrode films 11 is arbitrary.

Although the stacked body 15 is provided on the substrate 10 in the example of FIG. 1, a layer that includes circuit elements, interconnects, etc., may be formed on the substrate 10 as a foundation; and the stacked body 15 may be provided on the layer.

An insulating film 12 is provided on the stacked body 15. The insulating film 12 includes silicon oxide, etc.

The columnar portions 20 are multiply provided inside the stacked body 15. The columnar portions 20 extend through the stacked body 15 in the Z-direction. For example, the columnar portions 20 are formed in circular columnar configurations or elliptical columnar configurations. The upper ends of the columnar portions 20 are connected to contacts 40; and the columnar portions 20 are connected via the contacts 40 to bit lines BL extending in the Y-direction.

The interconnect portions 18 are multiply provided inside the stacked body 15. For example, the interconnect portions 18 include a metal such as tungsten, etc. The interconnect portions 18 extend in the X-direction and the Z-direction. The lower ends of the interconnect portions 18 are positioned on the substrate 10 and are electrically connected to the substrate 10. The upper ends of the interconnect portions 18 are connected to source lines SL via contacts 41. The interconnect portions 18 are provided inside slits ST formed in the stacked body 15. Insulating films (not illustrated) that are for insulating from the multiple electrode films 11 of the stacked body 15 are provided on the two Y-direction sides of each of the interconnect portions 18. Also, insulating members that are for separating the stacked bodies 15 from each other may be provided inside the slits ST instead of providing the interconnect portions 18.

As shown in FIG. 2, the multiple electrode films 11 of the stacked body 15 include a source-side select gate, a drain-side select gate, and word lines. For example, among the multiple electrode films 11 of the stacked body 15, the source-side select gate corresponds to an electrode film (a first electrode film) 11A of the lowermost layer; and the drain-side select gate corresponds to an electrode film 11D of the uppermost layer. For example, the word lines correspond to the electrode films 11 other than the electrode film 11A of the lowermost layer and the electrode film 11D of the uppermost layer. For example, the word lines correspond to an electrode film (a second electrode film) 11B and an electrode film 11C.

For example, at least one of the electrode film 11B or 11C of the multiple electrode films 11 may function as the source-side select gate. For example, the electrode films 11B and 11C of the multiple electrode films 11 may be dummy electrode films. Here, a dummy electrode film is an electrode film that is not selected in a read operation or a program operation and corresponds to an electrode film to which a programming voltage or a read voltage for a memory cell is not supplied. The electrode films 11 that are not dummy electrode films correspond to the electrode films 11 selected in the read operation and/or the program operation.

For example, among the multiple electrode films 11, the material(s) included in the electrode film 11A are different from the material(s) included in the electrode films 11B, 11C, and 11D. For example, the electrode film 11A includes polysilicon; and the electrode films 11B, 11C, and 11D include a metal such as tungsten, etc. A main body portion that is made of, for example, tungsten and a barrier metal layer that is made from, for example, titanium nitride (TiN) and covers the surface of the main body portion may be provided in the electrode films 11B, 11C, and 11D.

For example, the thickness in the Z-direction of the electrode film 11A is thicker than the thicknesses in the Z-direction of the electrode films 11B, 11C, and 11D. For example, a thickness T1 of the electrode film 11A is thicker than a thickness T2 of the electrode film 11B.

The columnar portion 20 includes a core film 9, a channel film (a semiconductor portion) 8, a tunneling insulating film (a second insulating film) 7, a charge storage film 6, and a blocking insulating film (a third insulating film) 5.

The core film 9 is an insulative film and includes, for example, silicon oxide. The configuration of the core film 9 is, for example, a circular columnar configuration. The core film 9 may not be provided in the columnar portion 20.

The channel film 8 is provided at the periphery of the core film 9. The channel film 8 is a semiconductor portion and includes, for example, polysilicon. The configuration of the channel film 8 is, for example, a tubular configuration including a bottom. The lower end of the channel film 8 contacts the substrate 10. As shown in FIG. 1, the upper end of the channel film 8 is connected to the contact 40 provided inside the insulating film 12. Thereby, the channel film 8 is connected to the bit line BL via the contact 40.

The tunneling insulating film 7 is provided at the periphery of the channel film 8. The tunneling insulating film 7 includes, for example, silicon oxide. The configuration of the tunneling insulating film 7 is, for example, a circular tube. The tunneling insulating film 7 is a potential barrier between the charge storage film 6 and the channel film 8. When programming, information is programmed by electrons tunneling through the tunneling insulating film 7 from the channel film 8 into the charge storage film 6. On the other hand, when erasing, the information that is stored is erased by holes tunneling through the tunneling insulating film 7 from the channel film 8 into the charge storage film 6 to cancel the charge of the electrons.

The charge storage film 6 is provided at the periphery of the tunneling insulating film 7. The charge storage film 6 includes, for example, silicon nitride (SiN). The configuration of the charge storage film 6 is, for example, a circular tube. Memory cells that include the charge storage film 6 are formed at the crossing portions between the channel film 8 and the electrode films 11. The charge storage film 6 includes trap sites that trap charge inside a layer. The threshold voltage of the memory cell changes according to the existence or absence of the charge trapped in the trap sites and the amount of the trapped charge. Thereby, the memory cell stores the information.

In the semiconductor memory device 1, many memory cells that each include the charge storage film 6 are arranged in a three-dimensional lattice configuration along the X-direction, the Y-direction, and the Z-direction; and data can be stored in each of the memory cells.

The blocking insulating film 5 is provided at the periphery of the charge storage film 6. The blocking insulating film 5 includes, for example, silicon oxide. The blocking insulating film 5 may be a stacked body of a film including silicon oxide and a film including a highly dielectric insulator such as aluminum oxide (AlO), etc. The configuration of the blocking insulating film 5 is, for example, a circular tube. For example, the blocking insulating film 5 protects the charge storage film 6 from the etching when forming the electrode films 11.

As shown in FIG. 2, the columnar portion 20 is provided inside a memory hole MH formed in the stacked body 15. The memory hole MH includes a first hole MH1 and a second hole MH2. The bottom surface of the first hole MH1 is positioned on the substrate 10; and the second hole MH2 is positioned on the first hole MH1 so that the second hole MH2 is formed as one body with the first hole MH1. The first hole MH1 and the second hole MH2 are through-holes.

The diameter of the first hole MH1 formed in the electrode film 11A of the multiple electrode films 11 is smaller than the diameter of the second hole MH2 formed in the electrode films 11 (e.g., the electrode films 11B, 11C, and 11D) other than the electrode film 11A. The diameter of the first hole MH1 is smaller than the diameter of the second hole MH2; therefore, a level difference S is formed inside the stacked body 15 at the boundary between the first hole MH1 and the second hole MH2 as shown in FIG. 2. The blocking insulating film 5, the charge storage film 6, and the tunneling insulating film 7 are positioned to cover the level difference S at the level difference S of the stacked body 15.

In the stacked body 15, the first hole MH1 corresponds to a hole formed in an insulating film (a first insulating film) 3A of the lowermost layer of the multiple insulating films 3 and the electrode film 11A of the lowermost layer of the multiple electrode films 11. The second hole MH2 corresponds to a hole formed in a portion of the stacked body 15 other than the insulating film 3A and the electrode film 11A. In a direction perpendicular to the Z-direction, a width (a first width) W1 of the first hole MH1 positioned inside the electrode film 11A is smaller than a width (a second width) W2 of the second hole MH2 positioned inside the second electrode film 11B. Also, in the direction perpendicular to the Z-direction, the width (a third width) W1 of the first hole MH1 positioned inside the insulating film 3A of the lowermost layer is substantially the same as the width (the first width) W1 of the first hole MH1 positioned inside the electrode film 11A. In the example of FIG. 2, the widths W1 and W2 correspond to widths in the Y-direction.

For example, it is desirable that the width W2 is not less than 1.3 times the width W1 and not more than 1.5 times the width W1. The width W2 may be a width within a range greater than 1.0 time the width W1 and smaller than 2.0 times the width W1.

Here, the width of a hole corresponds to the width of the hole in a direction perpendicular to the Z-direction, and in the case where the configuration of the hole is, for example, a circular column, corresponds to a width determined by a straight line passing through the center to connect between outer edges of the circular column. As shown in FIG. 3, the width W1 of the first hole MH1 having the circular columnar configuration is determined by a straight line passing through a center C and connecting between outer edges t1 and t2 of the circular column. That is, the width W1 of the first hole MH1 corresponds to the diameter of the circular column.

FIG. 3 corresponds to a drawing of the first hole MH1 formed in the electrode film 11A when viewed from the upper surface. The columnar portion 20 that includes the core film 9, the channel film 8, the tunneling insulating film 7, the charge storage film 6, and the blocking insulating film 5 is positioned inside the first hole MH1; and the width of the first hole MH1 corresponds to the width of the columnar portion 20.

Accordingly, among the multiple electrode films 11, the diameter of the first hole MH1 formed in the electrode film 11A is smaller than the diameter of the second hole MH2 formed in the electrode films 11 (e.g., the electrode films 11B, 11C, and 11D) other than the electrode film 11A. The diameter of the first hole MH1 is smaller than the diameter of the second hole MH2; therefore, the level difference S is formed inside the stacked body 15 at the boundary between the first hole MH1 and the second hole MH2 as shown in FIG. 2. The blocking insulating film 5, the charge storage film 6, and the tunneling insulating film 7 are positioned to cover the level difference S at the level difference S of the stacked body 15.

For example, the width (the diameter) of the first hole MH1 is substantially the same at positions in the Z-direction. That is, the width (the diameter) of the first hole MH1 inside the insulating film 3A is substantially the same as the width (the diameter) of the first hole MH1 inside the electrode film 11A.

For example, the width (the diameter) of the second hole MH2 is substantially the same at positions in the Z-direction. For example, the width (the diameter) of the second hole MH2 inside the electrode film 11B, the width (the diameter) of the second hole MH2 inside the electrode film 11C, and the width (the diameter) of the second hole MH2 inside the electrode film 11D are substantially the same.

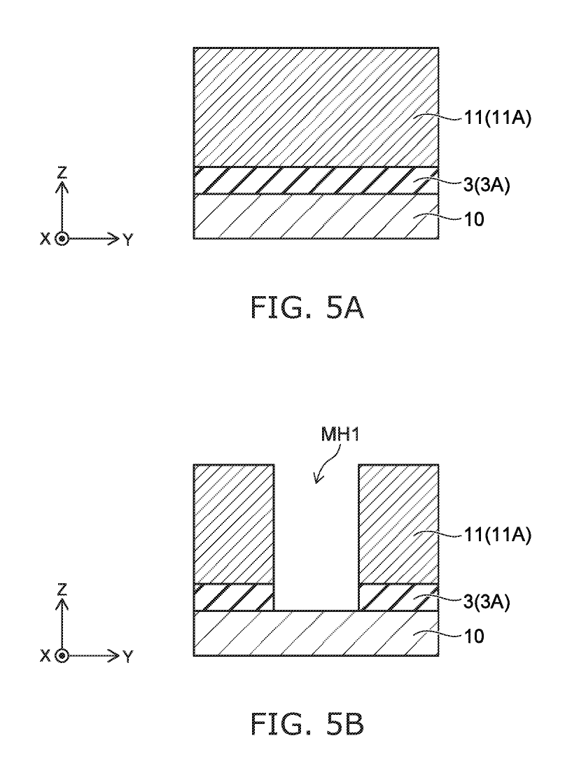

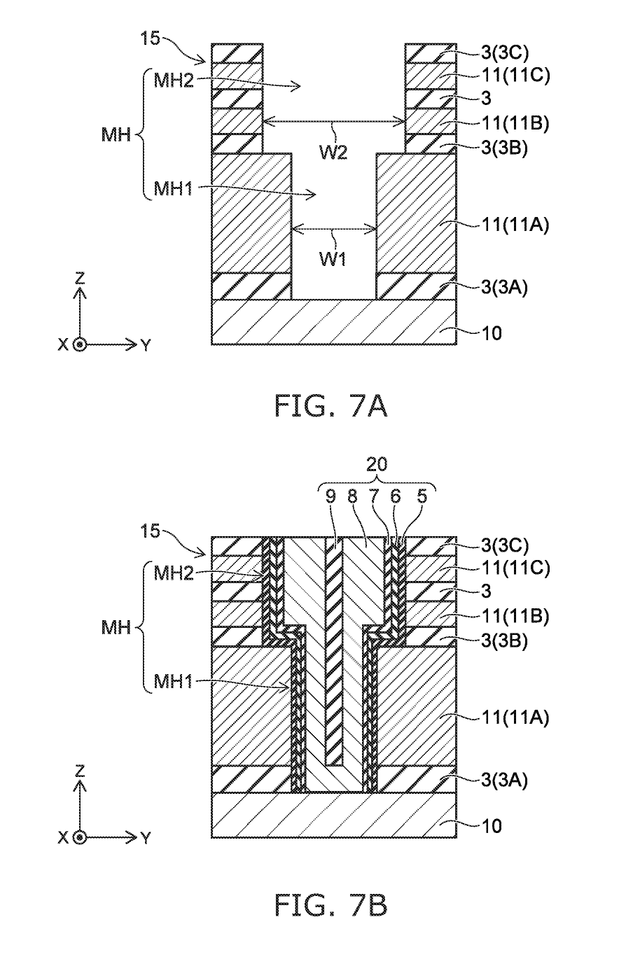

The width (the diameter) of the hole being substantially the same at positions in the Z-direction includes the case where the width (the diameter) of the hole is partially different at positions in the Z-direction due to the configuration of the hole changing due to effects of heat, etc., when forming the first hole MH1 and the second hole MH2 such as in the processes of FIG. 5B and FIG. 7A described below or in subsequent processes. For example, according to the formation conditions, there are also cases where the diameter of the hole becomes small unintentionally at a lower layer. Such cases also are included in being “substantially the same width at positions in the first direction.”

Electrical characteristics of the electrode film 11A functioning as the source-side select gate will now be described.

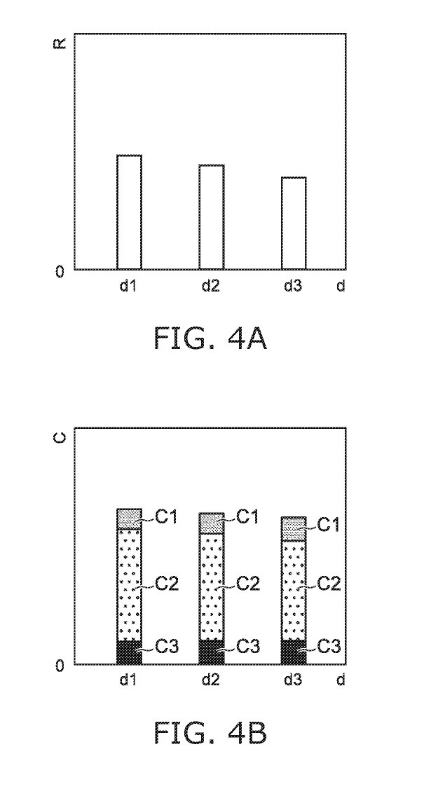

FIG. 4A and FIG. 4B are drawings showing the relationship of the diameter of the first hole MH1 with the interconnect resistance and the interconnect capacitance of the electrode film 11A.

FIG. 4A shows the relationship between the diameter of the first hole MH1 and the interconnect resistance of the electrode film 11A. The vertical axis is the value of an interconnect resistance R of the electrode film 11A; and the units of the interconnect resistance R are, for example, ohms (Ω). The horizontal axis is the value of a diameter d of the first hole MH1; and the units of the diameter d are, for example, nanometers. In FIG. 4A, the value of the interconnect resistance R is shown for the case where the diameter d of the first hole MH1 is changed (diameters d1, d2, and d3). The diameter d1 is larger than the diameter d2; and the diameter d2 is larger than the diameter d3.

Comparing the interconnect resistances R for the diameter d1, the diameter d2, and the diameter d3 as shown in FIG. 4A, it was found that the value of the interconnect resistance R decreases as the diameter d of the first hole MH1 decreases. This is because the value of the interconnect resistance R decreases because the volume of the electrode film 11A (e.g., the polysilicon film) between the slits ST (referring to FIG. 1) increases as the diameter d of the first hole MH1 decreases as in the diameter d1, the diameter d2, and the diameter d3.

FIG. 4B shows the relationship between the diameter of the first hole MH1 and the interconnect capacitance of the electrode film 11A. The vertical axis is the value of an interconnect capacitance C of the electrode film 11A; and the units of the interconnect capacitance C are, for example, farads (F). The horizontal axis is the value of the diameter d of the first hole MH1; and the units of the diameter d are, for example, nanometers. In FIG. 4B, the value of the interconnect capacitance C is shown for the case where the diameter d of the first hole MH1 is changed (the diameters d1, d2, and d3). The diameter d1 is larger than the diameter d2; and the diameter d2 is larger than the diameter d3.

In the figure, an interconnect capacitance C1 corresponds to the interconnect capacitance at the upper portion of the electrode film 11A. In FIG. 2, an insulating film 3B is provided on the upper surface of the electrode film 11A. In the figure, an interconnect capacitance C2 corresponds to the interconnect capacitance at the portion of the electrode film 11A opposing the first hole MH1. In FIG. 2, the blocking insulating film 5 is provided at the surface of the electrode film 11A opposing the first hole MH1. In the figure, an interconnect capacitance C3 corresponds to the interconnect capacitance at the lower portion of the electrode film 11A. In FIG. 2, the insulating film 3A is provided on the lower surface of the electrode film 11A.

Accordingly, in FIG. 4B, the interconnect capacitance C of the electrode film 11A is the sum of the interconnect capacitance C1, the interconnect capacitance C2, and the interconnect capacitance C3.

Comparing the interconnect capacitances C (the interconnect capacitances C1, C2, and C3) for the diameter d1, the diameter d2, and the diameter d3 as shown in FIG. 4B, it was found that the value of the interconnect capacitance C2 decreases as the diameter d of the first hole MH1 decreases. Accordingly, it was found that the value of the interconnect capacitance C decreases as the diameter d of the first hole MH1 decreases. This is because the value of the interconnect capacitance C2 at the portion of the electrode film 11A opposing the first hole MH1 decreases because the circumference of the first hole MH1 decreases as the diameter d of the first hole MH1 decreases as in the diameter d1, the diameter d2, and the diameter d3.

From FIG. 4A and FIG. 4B, it was found that the interconnect resistance and the interconnect capacitance of the electrode film 11A can be reduced by reducing the diameter of the first hole MH1 formed in the electrode film 11A. Accordingly, the transistor function of the select transistor is improved by reducing the diameter of the first hole MH1 formed in the electrode film 11A.

A method for manufacturing the semiconductor memory device according to the embodiment will now be described.

FIG. 5A and FIG. 5B to FIG. 7A and FIG. 7B are cross-sectional views showing the method for manufacturing the semiconductor memory device 1. FIG. 5A and FIG. 5B to FIG. 7A and FIG. 7B show a portion of a region corresponding to FIG. 2 and show a portion of an insulating film 3C and below in FIG. 2.

First, as shown in FIG. 5A, after forming the insulating film 3A on the substrate 10 by, for example, CVD (Chemical Vapor Deposition), the electrode film 11A is formed on the insulating film 3A. The insulating film 3A is formed of, for example, silicon oxide; and the electrode film 11A is formed of, for example, polysilicon.

Then, as shown in FIG. 5B, the first hole MH1 is formed in the insulating film 3A and the electrode film 11A by, for example, photolithography and RIE (Reactive Ion Etching). The first hole MH1 pierces the insulating film 3A and the electrode film 11A and reaches the substrate 10. In the case where the first hole MH1 is multiply formed, for example, the multiple first holes MH1 are formed in a lattice configuration when viewed from the Z-direction.

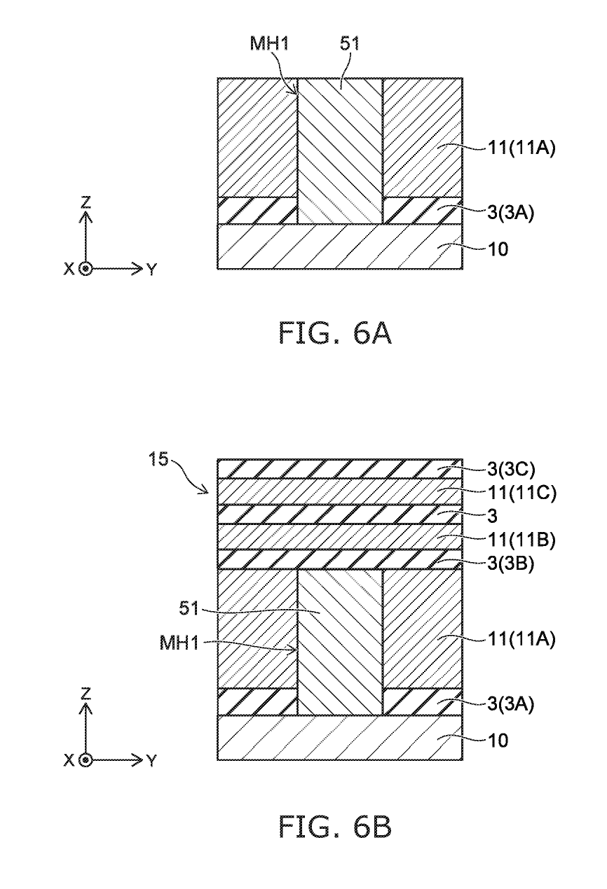

Continuing as shown in FIG. 6A, a film 51 is formed inside the first hole MH1 by, for example, CVD. The film 51 is formed of, for example, silicon oxide.

Then, as shown in FIG. 6B, the insulating films 3 and the electrode films 11 are stacked alternately on the electrode film 11A and the film 51 by, for example, CVD. The electrode films 11 are formed of, for example, a metal material. Thereby, the stacked body 15 that includes the multiple electrode films 11 and the multiple insulating films 3 is formed. For example, in the stacked body 15, the electrode film 11A of the lowermost layer is formed of polysilicon; and the electrode films 11 other than the electrode film 11A of the lowermost layer are formed of tungsten.

Continuing as shown in FIG. 7A, the second hole MH2 is formed in the stacked body 15 by, for example, photolithography and RIE. The second hole MH2 pierces the insulating films 3 and the electrode films 11 to be positioned directly above the first hole MH1. Thereby, portions of the upper surface of the film 51 and the upper surface of the electrode film 11A are exposed. In the photolithography, it is desirable to perform positional alignment of the second hole MH2 to be positioned directly above the first hole MH1 by considering the positional shift of the second hole MH2 with respect to the first hole MH1.

Continuing, the film 51 that is inside the first hole MH1 is removed via the second hole MH2 by performing etching such as RIE, etc. The film 51 is removed; and the memory hole MH that includes the first hole MH1 and the second hole MH2 is formed. The width W1 of the first hole MH1 is narrower than the width W2 of the second hole MH2.

Then, as shown in FIG. 7B, the blocking insulating film 5 is formed on the inner surface of the memory hole MH by, for example, CVD. The blocking insulating film 5 is formed of, for example, silicon oxide. Continuing, the charge storage film 6 is formed on the blocking insulating film 5 inside the memory hole MH. For example, the charge storage film 6 is formed of silicon nitride. Subsequently, the tunneling insulating film 7 is formed on the charge storage film 6 inside the memory hole MH. The tunneling insulating film 7 is formed of, for example, silicon oxide.

Continuing, the core film 9 is formed after forming the channel film 8 inside the memory hole MH by, for example, CVD. The channel film 8 is formed of, for example, polysilicon; and the core film 9 is formed of, for example, silicon oxide. Thereby, the columnar portion 20 that includes the core film 9, the channel film 8, the tunneling insulating film 7, the charge storage film 6, and the blocking insulating film 5 is formed.

Subsequently, the insulating film 12 (referring to FIG. 1 and FIG. 2) is formed by depositing silicon oxide on the stacked body 15 and the columnar portion 20. Continuing, the multiple slits ST that extend in the X-direction and the Z-direction (referring to FIG. 1) are formed in the stacked body 15 and the insulating film 12 by performing etching such as RIE, etc. The slits ST pierce the insulating film 12 and the stacked body 15 in the Z-direction and reach the substrate 10. Subsequently, the interconnect portions 18 are formed by filling a metal material such as tungsten, etc., into the slits ST. Then, by using well-known methods, the contacts 40 and the bit lines BL that are connected to the channel films 8 are formed; and the contacts 41 and the source lines SL that are connected to the interconnect portions 18 are formed.

Thus, the semiconductor memory device 1 according to the embodiment is manufactured.

The stacked body may be formed by alternately stacking the insulating films 3 and sacrificial films on the electrode film 11A and the film 51 in the process of FIG. 6B; subsequently, the sacrificial films of the stacked body may be selectively removed via the slits ST after the formation of the columnar portion 20 in the process of FIG. 7B; and the electrode films 11 may be formed inside gaps formed by the removal of the sacrificial films. By performing such processes, the stacked body 15 that includes the multiple electrode films 11 and the multiple insulating films 3 is formed.

Effects of the embodiment will now be described.

In the semiconductor memory device that has the three-dimensional structure, the electrode films of the multiple electrode films provided at the upper layer and the lower layer of the stacked body function as the gate electrodes of the select transistors; and a memory string is configured by connecting, via a channel, the select transistors and the memory cells positioned between the select transistors.

For example, in the case where the electrode film of the lowermost layer of the multiple electrode films is formed of polysilicon, there is a risk that the resistivity of the electrode film may be high compared to the case where a metal material is used. Thereby, an interconnect delay (RC delay) occurs easily due to the increase of the interconnect resistance of the electrode film of the lowermost layer. Thereby, the electrical characteristics of the semiconductor memory device degrade.

Here, it may be considered to set the thickness in the Z-direction of the electrode film to be thick to reduce the interconnect resistance of the electrode film of the lowermost layer. However, it is difficult to eliminate the interconnect delay by setting the thickness in the Z-direction of the electrode film to be thick because the interconnect capacitance of the electrode film undesirably increases.

In the semiconductor memory device 1 of the embodiment, the diameter of the first hole MH1 formed in the electrode film 11A of the lowermost layer of the multiple electrode films 11 of the stacked body 15 is smaller than the diameter of the second hole MH2 formed in one of the electrode films 11 other than the electrode film 11A of the lowermost layer. By reducing the diameter of the first hole MH1 formed in the electrode film 11A of the lowermost layer, the interconnect resistance and the interconnect capacitance of the electrode film 11 can be reduced.

For example, as shown in FIG. 4A and FIG. 4B, the interconnect resistance and the interconnect capacitance of the electrode film 11A can be reduced by reducing the diameter of the first hole MH1 formed in the electrode film 11A. Accordingly, the transistor function of the select transistor is improved.

According to the embodiment, a semiconductor memory device and a method for manufacturing the semiconductor memory device are provided in which the electrical characteristics are improved.

### Second Embodiment

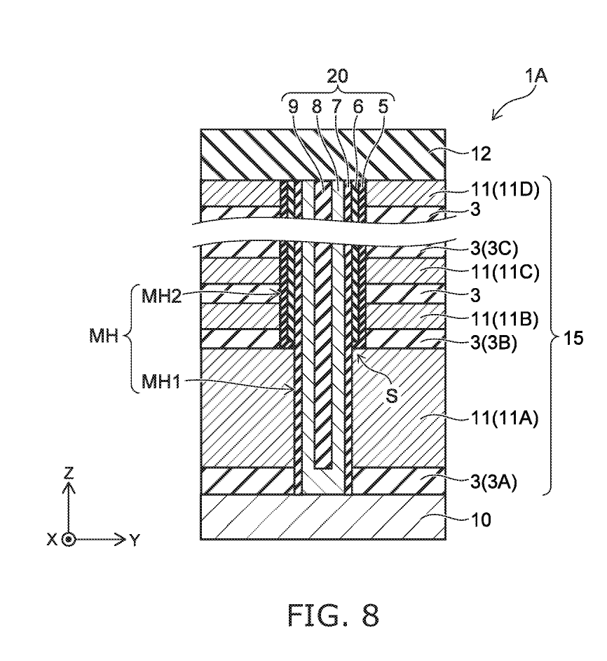

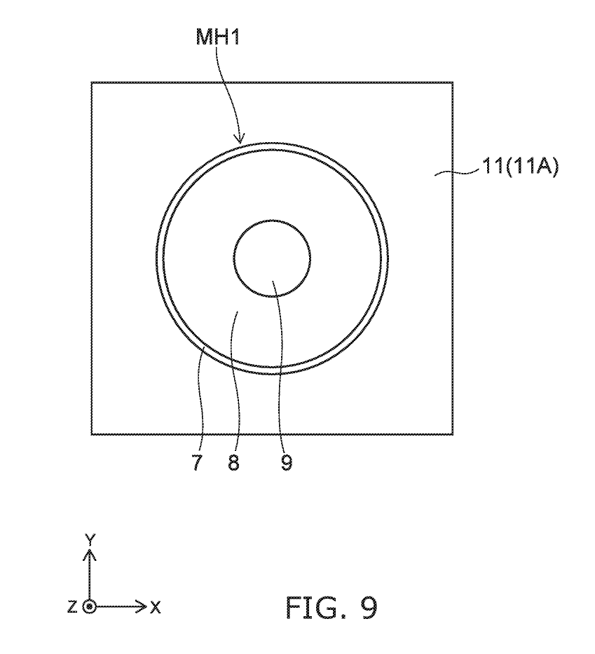

FIG. 8 is a cross-sectional view of a portion of a semiconductor memory device 1A. FIG. 9 is a top view of a portion of the semiconductor memory device 1A.

The regions shown in FIG. 8 and FIG. 9 correspond respectively to the regions shown in FIG. 2 and FIG. 3.

The element that is formed inside the first hole MH1 of the memory hole MH in the semiconductor memory device 1A according to the embodiment is different from that of the semiconductor memory device 1 according to the first embodiment. Otherwise, the configuration is the same as that of the first embodiment; and a detailed description is therefore omitted.

As shown in FIG. 8, the columnar portion 20 is provided inside the memory hole MH formed in the stacked body 15. The memory hole MH includes the first hole MH1 and the second hole MH2. In the stacked body 15, the first hole MH1 corresponds to a hole formed in the insulating film 3A of the lowermost layer of the multiple insulating films 3 and the electrode film 11A of the lowermost layer of the multiple electrode films 11. The second hole MH2 corresponds to a hole formed in a portion of the stacked body 15 other than the insulating film 3A and the electrode film 11A.

The columnar portion 20 includes the core film 9, the channel film 8, the tunneling insulating film 7, the charge storage film 6, and the blocking insulating film 5. As shown in FIG. 9, the core film 9, the channel film 8, and the tunneling insulating film 7 of the columnar portion 20 are positioned inside the first hole MH1.

The core film 9, the channel film 8, the tunneling insulating film 7, the charge storage film 6, and the blocking insulating film 5 of the columnar portion 20 are positioned inside the second hole MH2.

For example, the tunneling insulating film 7 that is positioned inside the first hole MH1 and the second hole MH2 has a tubular configuration. For example, the charge storage film 6 that is positioned inside the second hole MH2 has a tubular configuration. For example, the blocking insulating film 5 that is positioned inside the second hole MH2 has a tubular configuration. The blocking insulating film 5 covers the side surface and the bottom surface of the charge storage film 6 and has an L-shaped configuration when viewed from the X-direction.

The blocking insulating film 5 and the tunneling insulating film 7 are positioned to cover the level difference S at the level difference S of the stacked body 15.

A method for manufacturing the semiconductor memory device according to the embodiment will now be described.

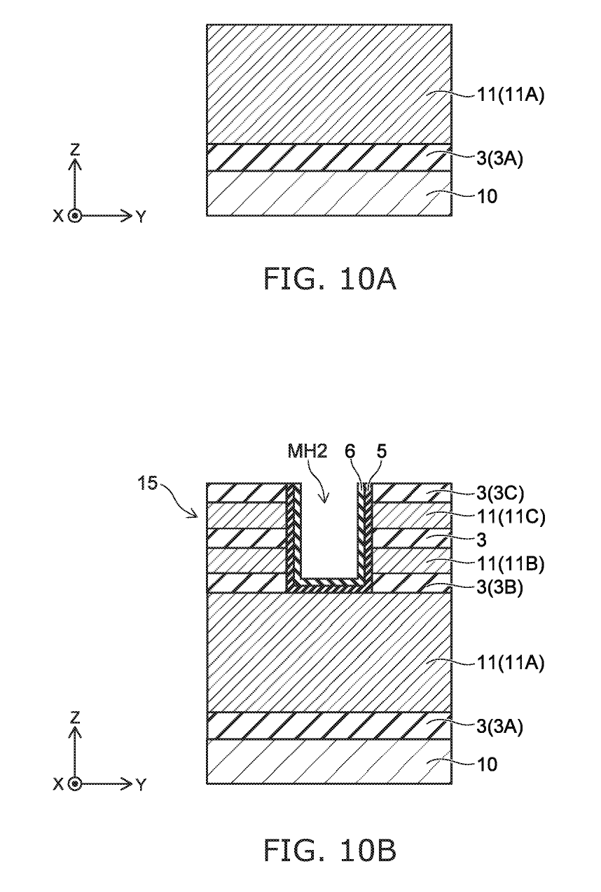

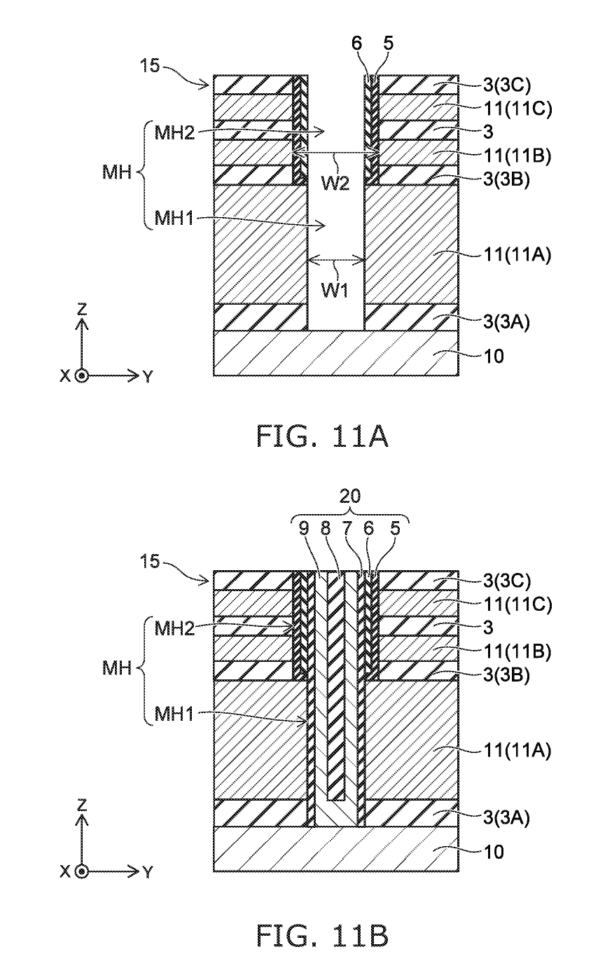

FIG. 10A, FIG. 10B, FIG. 11A, and FIG. 11B are cross-sectional views showing the method for manufacturing the semiconductor memory device 1A. FIG. 10A, FIG. 10B, FIG. 11A, and FIG. 11B show a portion of the region corresponding to FIG. 8 and show a portion of the insulating film 3C and below in FIG. 8.

First, as shown in FIG. 10A, the insulating film 3A is formed on the substrate 10; subsequently, the electrode film 11A is formed on the insulating film 3A.

Then, as shown in FIG. 10B, the stacked body 15 is formed by alternately stacking the insulating films 3 and the electrode films 11 on the electrode film 11A. Continuing, the second hole MH2 is formed in the stacked body 15 by, for example, photolithography and RIE. The second hole MH2 pierces the insulating films 3 and the electrode films 11; and a portion of the upper surface of the electrode film 11A is exposed.

Continuing, the blocking insulating film 5 is formed on the inner surface of the second hole MH2 by, for example, CVD; subsequently, the charge storage film 6 is formed on the blocking insulating film 5 inside the second hole MH2. For example, the blocking insulating film 5 is formed of silicon oxide; and the charge storage film 6 is formed of silicon nitride.

Then, as shown in FIG. 11A, a portion of the charge storage film 6, a portion of the blocking insulating film 5, a portion of the electrode film 11A, and a portion of the insulating film 3A are removed via the second hole MH2 by performing etching such as RIE, etc. Thereby, the first hole MH1 is formed; and the memory hole MH that includes the first hole MH1 and the second hole MH2 is formed. When forming the first hole MH1, a portion of the charge storage film 6 and a portion of the blocking insulating film 5 function as a mask; therefore, the width W1 of the first hole MH1 is narrower than the width W2 of the second hole MH2. The blocking insulating film 5 covers the side surface and the bottom surface of the charge storage film 6 and has an L-shaped configuration when viewed from the X-direction.

Continuing as shown in FIG. 11B, the tunneling insulating film 7 is formed on the charge storage film 6, the blocking insulating film 5, the electrode film 11A, and the insulating film 3A inside the memory hole MH by, for example, CVD. The tunneling insulating film 7 is formed of, for example, silicon oxide. Continuing, inside the memory hole MH, the channel film 8 is formed; subsequently, the core film 9 is formed. Thereby, the columnar portion 20 that includes the core film 9, the channel film 8, the tunneling insulating film 7, the charge storage film 6, and the blocking insulating film 5 is formed.

Subsequently, the insulating film 12 (referring to FIG. 8) is formed on the stacked body 15 and the columnar portion 20. Continuing, the multiple slits ST (referring to FIG. 1) are formed in the stacked body 15 and the insulating film 12; and the interconnect portions 18 are formed inside the slits ST. Then, by well-known methods, the contacts 40 and the bit lines BL that are connected to the channel films 8 are formed; and the contacts 41 and the source lines SL that are connected to the interconnect portions 18 are formed.

Thus, the semiconductor memory device 1A according to the embodiment is manufactured.

Although the tunneling insulating film 7 is formed inside the first hole MH1 of the memory hole MH by depositing silicon oxide on the electrode film 11A in the process of FIG. 11B, the tunneling insulating film 7 may be formed by performing thermal oxidation of a portion of the electrode film 11A (the polysilicon film) via the memory hole MH.

The effects of the second embodiment are the same as the effects of the first embodiment.

### Third Embodiment

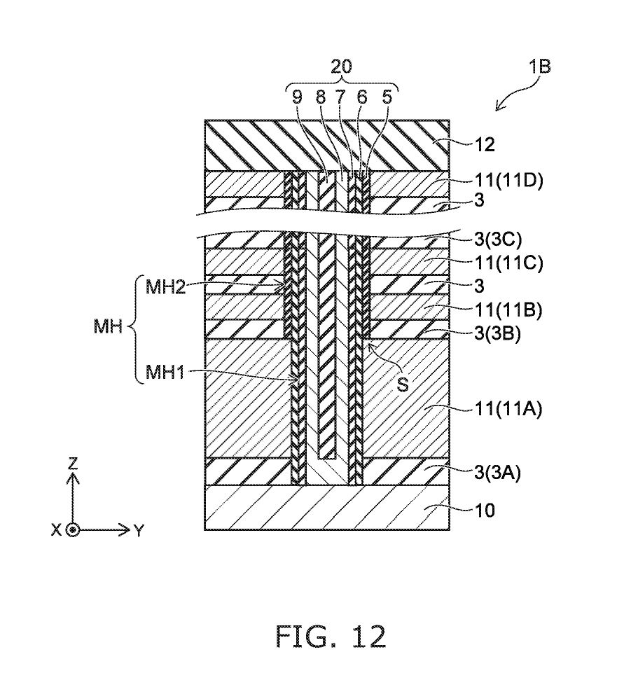

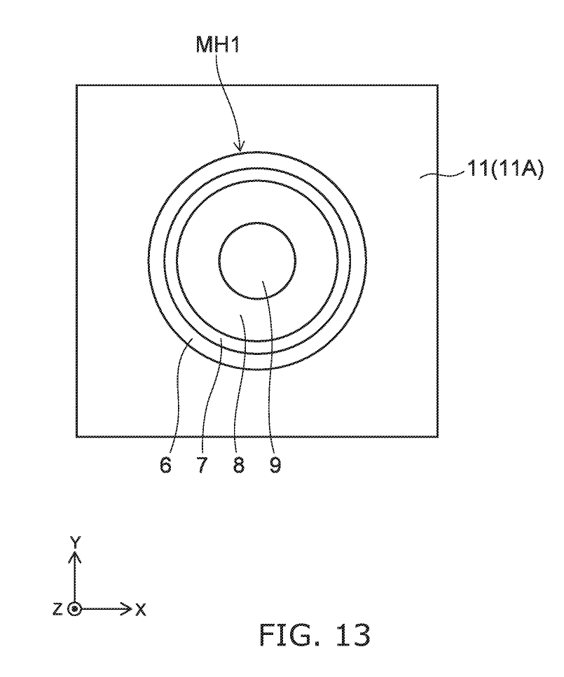

FIG. 12 is a cross-sectional view of a portion of a semiconductor memory device 18. FIG. 13 is a top view of a portion of the semiconductor memory device 18.

The regions shown in FIG. 12 and FIG. 13 correspond respectively to the regions shown in FIG. 2 and FIG. 3.

The element that is formed inside the first hole MH1 of the memory hole MH in the semiconductor memory device 18 according to the embodiment is different from that of the semiconductor memory device 1 according to the first embodiment. Otherwise, the configuration is the same as that of the first embodiment; and a detailed description is therefore omitted.

As shown in FIG. 12, the columnar portion 20 is provided inside the memory hole MH formed in the stacked body 15. The memory hole MH includes the first hole MH1 and the second hole MH2. In the stacked body 15, the first hole MH1 corresponds to a hole formed in the insulating film 3A of the lowermost layer of the multiple insulating films 3 and the electrode film 11A of the lowermost layer of the multiple electrode films 11. The second hole MH2 corresponds to a hole formed in a portion of the stacked body 15 other than the insulating film 3A and the electrode film 11A.

The columnar portion 20 includes the core film 9, the channel film 8, the tunneling insulating film 7, the charge storage film 6, and the blocking insulating film 5. As shown in FIG. 13, the core film 9, the channel film 8, the tunneling insulating film 7, and the charge storage film 6 of the columnar portion 20 are positioned inside the first hole MH1.

The core film 9, the channel film 8, the tunneling insulating film 7, the charge storage film 6, and the blocking insulating film 5 of the columnar portion 20 are positioned inside the second hole MH2.

For example, the tunneling insulating film 7 and the charge storage film 6 that are positioned inside the first hole MH1 and the second hole MH2 have tubular configurations. The blocking insulating film 5 that is positioned inside the second hole MH2 covers a portion of the side surface of the charge storage film 6 and has, for example, a tubular configuration.

The blocking insulating film 5 and the charge storage film 6 are positioned to cover the level difference S at the level difference S of the stacked body 15.

A method for manufacturing the semiconductor memory device according to the embodiment will now be described.

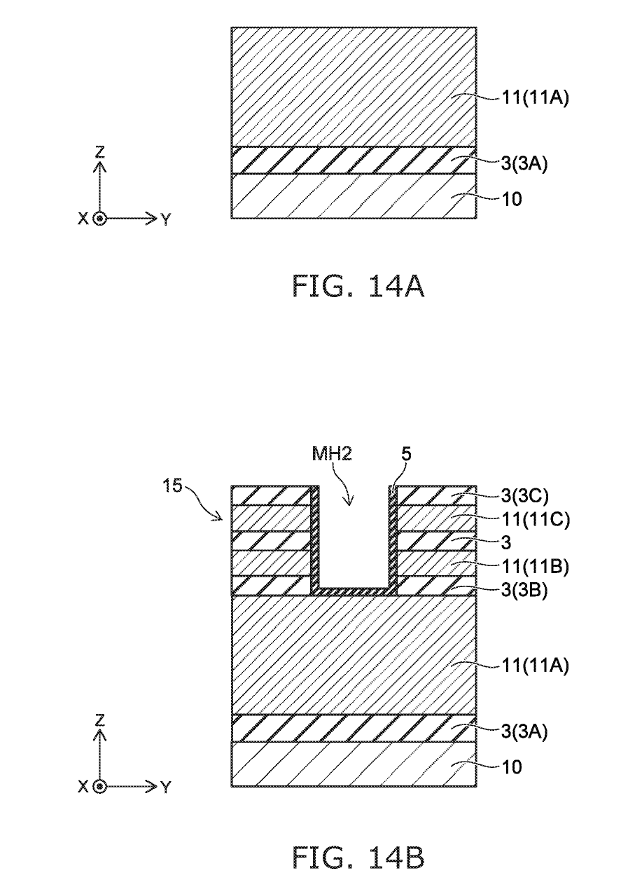

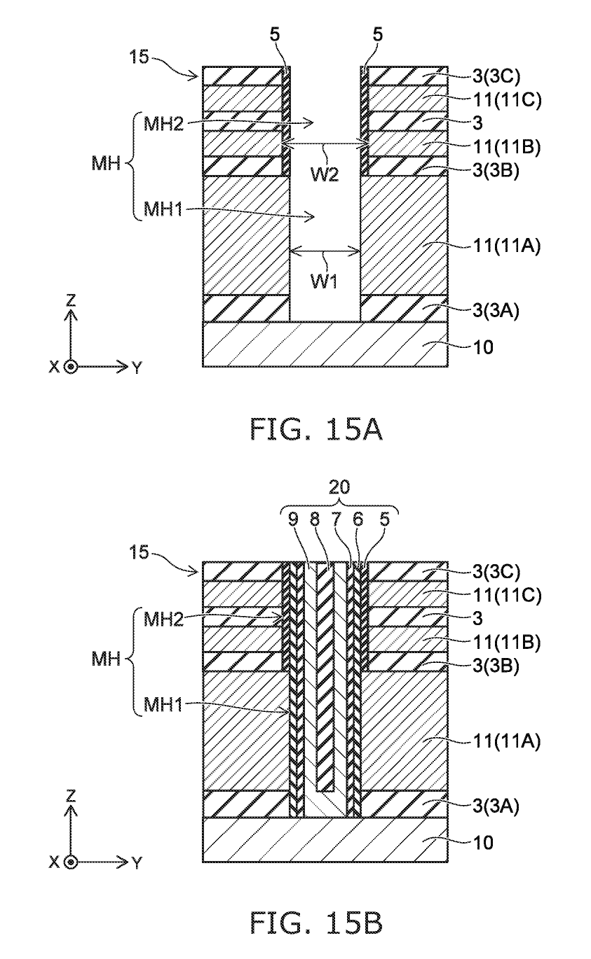

FIG. 14A, FIG. 14B, FIG. 15A, and FIG. 15B are cross-sectional views showing the method for manufacturing the semiconductor memory device 1B. FIG. 14A, FIG. 14B, FIG. 15A, and FIG. 15B show a portion of the region corresponding to FIG. 12 and show a portion of the insulating film 3C and below in FIG. 12.

First, as shown in FIG. 14A, the insulating film 3A is formed on the substrate 10; subsequently, the electrode film 11A is formed on the insulating film 3A.

Then, as shown in FIG. 14B, the stacked body 15 is formed by alternately stacking the insulating films 3 and the electrode films 11 on the electrode film 11A. Continuing, the second hole MH2 is formed in the stacked body 15 by, for example, photolithography and RIE. The second hole MH2 pierces the insulating films 3 and the electrode films 11; and a portion of the upper surface of the electrode film 11A is exposed. Continuing, the blocking insulating film 5 is formed on the inner surface of the second hole MH2 by, for example, CVD. For example, the blocking insulating film 5 is formed of silicon oxide.

Then, as shown in FIG. 15A, a portion of the blocking insulating film 5, a portion of the electrode film 11A, and a portion of the insulating film 3A are removed via the second hole MH2 by performing etching such as RIE, etc. Thereby, the first hole MH1 is formed. Also, the memory hole MH that includes the first hole MH1 and the second hole MH2 is formed. When forming the first hole MH1, a portion of the blocking insulating film 5 functions as a mask; therefore, the width W1 of the first hole MH1 is narrower than the width W2 of the second hole MH2.

Continuing as shown in FIG. 15B, the charge storage film 6 is formed on the blocking insulating film 5, the electrode film 11A, and the insulating film 3A inside the memory hole MH by, for example, CVD. The charge storage film 6 is formed of, for example, silicon nitride. Continuing, the tunneling insulating film 7 is formed on the charge storage film 6 inside the memory hole MH by, for example, CVD. The tunneling insulating film 7 is formed of, for example, silicon oxide.

Continuing, inside the memory hole MH, the channel film 8 is formed; subsequently, the core film 9 is formed. Thereby, the columnar portion 20 that includes the core film 9, the channel film 8, the tunneling insulating film 7, the charge storage film 6, and the blocking insulating film 5 is formed.

Subsequently, the insulating film 12 (referring to FIG. 12) is formed on the stacked body 15 and the columnar portion 20. Continuing, the multiple slits ST (referring to FIG. 1) are formed in the stacked body 15 and the insulating film 12; and the interconnect portions 18 are formed inside the slits ST. Then, by well-known methods, the contacts 40 and the bit lines BL that are connected to the channel film 8 are formed; and the contacts 41 and the source lines SL that are connected to the interconnect portions 18 are formed.

Thus, the semiconductor memory device 1B according to the embodiment is manufactured.

The effects of the third embodiment are the same as the effects of the first embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions. Additionally, the embodiments described above can be combined mutually.

What is claimed is:

1. A semiconductor memory device, comprising:
a substrate;
a stacked body provided on the substrate, the stacked body including a plurality of electrode films stacked in a first direction to be separated from each other; and
a columnar portion provided inside the stacked body, the columnar portion including a semiconductor portion extending in the first direction, the columnar portion having a plurality of widths having mutually-different sizes in a second direction perpendicular to the first direction,
the plurality of widths including a first width and a second width, the first width being a width of the columnar portion positioned inside a first electrode film of a lowermost layer of the plurality of electrode films, the first width being substantially the same width at positions in the first direction of the columnar portion, the second width being a width of the columnar portion positioned inside a second electrode film of the plurality of electrode films, the second width being substantially the same width at positions in the first direction of the columnar portion,
the first width being smaller than the second width.

2. The device according to claim 1, wherein
the stacked body further includes a plurality of insulating films stacked alternately with the plurality of electrode films,
the plurality of insulating films includes a first insulating film provided between the substrate and the first electrode film,
the plurality of widths further includes a third width, the third width being a width of the columnar portion positioned inside the first insulating film, the third width being substantially the same width at positions in the first direction of the columnar portion, and
the third width is substantially the same as the first width.

3. The device according to claim 1, wherein the columnar portion further includes a second insulating film provided between the semiconductor portion and the stacked body, a charge storage film provided between the second insulating film and the stacked body, and a third insulating film provided between the charge storage film and the stacked body.

4. The device according to claim 1, wherein the columnar portion further includes a second insulating film provided between the semiconductor portion and the stacked body, a charge storage film provided between the second insulating film and the second electrode film, and a third insulating film provided between the charge storage film and the second electrode film.

5. The device according to claim 1, wherein the columnar portion further includes a second insulating film provided between the semiconductor portion and the stacked body, a charge storage film provided between the second insulating film and the stacked body, and a third insulating film provided between the charge storage film and the second electrode film.

6. The device according to claim 1, wherein
the stacked body further includes a plurality of insulating films stacked alternately with the plurality of electrode films,
the plurality of insulating films includes a fourth insulating film provided between the first electrode film and the second electrode film,
the plurality of widths further includes a fourth width, the fourth width being a width of the columnar portion positioned inside the fourth insulating film, the fourth width being substantially the same width at positions in the first direction of the columnar portion, and
the fourth width is substantially the same as the second width.

7. The device according to claim 6, wherein
the columnar portion further includes a second insulating film provided between the semiconductor portion and the stacked body, a charge storage film provided between the second insulating film and the stacked body, and a third insulating film provided between the charge storage film and the stacked body, and
the third insulating film covers a level difference formed at the first electrode film.

8. The device according to claim 6, wherein
the columnar portion further includes a second insulating film provided between the semiconductor portion and the stacked body, a charge storage film provided between the second insulating film and the second electrode film and between the second insulating film and the fourth insulating film, and a third insulating film provided between the charge storage film and the second electrode film and between the charge storage film and the fourth insulating film, and
the second insulating film and the third insulating film cover a level difference formed at the first electrode film.

9. The device according to claim 8, wherein a configuration of the third insulating film is an L-shaped configuration in a cross section including the first direction and the second direction.

10. The device according to claim 6, wherein
the columnar portion further includes a second insulating film provided between the semiconductor portion and the stacked body, a charge storage film provided between the second insulating film and the stacked body, and a third insulating film provided between the charge storage film and the second electrode film and between the charge storage film and the fourth insulating film, and
the charge storage film and the third insulating film cover a level difference formed at the first electrode film.

11. The device according to claim 1, wherein the first electrode film includes a material different from the second electrode film.

12. The device according to claim 1, wherein the first electrode film includes polysilicon.

13. The device according to claim 1, wherein a thickness in the first direction of the first electrode film is thicker than a thickness in the first direction of the second electrode film.

14. The device according to claim 1, wherein the first electrode film is a source-side select gate.

15. A method for manufacturing a semiconductor memory device, comprising:
forming a first insulating film on a substrate;
forming a first electrode film on the first insulating film;
forming a first through-hole in the first insulating film and the first electrode film, the first through-hole piercing the first insulating film and the first electrode film and reaching the substrate;
forming a first film inside the first through-hole;
forming a stacked body on the first electrode film and the first film by alternately stacking a second insulating film and a second electrode film;
forming a second through-hole in the stacked body to pierce the stacked body and reach the first film, a width in a direction perpendicular to a stacking direction of the stacked body being larger for the second through-hole than for the first through-hole;
removing the first film inside the first through-hole via the second through-hole; and
forming a columnar portion inside the first through-hole and the second through-hole, the columnar portion including a semiconductor portion.

16. The method according to claim 15, wherein the forming of the columnar portion includes forming a third insulating film on inner surfaces of the first through-hole and the second through-hole, forming a charge storage film on the third insulating film inside the first through-hole and the second through-hole, and forming a fourth insulating film on the charge storage film inside the first through-hole and the second through-hole.

17. The method according to claim 15, wherein
the first electrode film is formed of polysilicon, and
the second electrode film is formed of tungsten.

18. A method for manufacturing a semiconductor memory device, comprising:
forming a first insulating film on a substrate;
forming a first electrode film on the first insulating film;
forming a stacked body on the first electrode film by alternately stacking a second insulating film and a second electrode film;
forming a first through-hole reaching the first electrode film by removing a portion of the stacked body;
forming a third insulating film on an inner surface of the first through-hole;
forming a second through-hole reaching the substrate by removing a portion of the third insulating film, a portion of the first electrode film, and a portion of the first insulating film via the first through-hole, a width in a direction perpendicular to a stacking direction of the stacked body being smaller for the second through-hole than for the first through-hole;
forming a fourth insulating film inside the first through-hole and the second through-hole; and
forming a semiconductor portion on the fourth insulating film inside the first through-hole and the second through-hole.

19. The method according to claim 18, further comprising forming a charge storage film on the third insulating film inside the first through-hole after the forming of the third insulating film,
the forming of the second through-hole including removing a portion of the charge storage film.

20. The method according to claim 18, further comprising forming a charge storage film inside the first through-hole and the second through-hole after the forming of the second through-hole.
